(19) United States
(12) Patent Application Publication
(10) Pub. No.: US 2016/0064181 A1
(43) Pub. Date: Mar. 3, 2016

(54) Device for Nanoscale Sample Manipulation

(71) Applicants: Mitra L. TAHERI, Philadelphia, PA (US); Hessam GHASSEMI, Jenkintown, PA (US)

(72) Inventors: Mitra L. Taheri, Philadelphia, PA (US); Hessam Ghassemi, Jenkintown, PA (US)

(73) Assignee: DREXEL UNIVERSITY, Philadelphia, PA (US)

(21) Appl. No.: 14/784,718

(22) PCT Filed: May 15, 2014
(86) PCT No.: PCT/US2014/038172

§ 371 Date: Oct. 15, 2015

Related U.S. Application Data
(60) Provisional application No. 61/824,719, filed on May 17, 2013.

(51) Int. Cl. H01J 37/20; B25J 7/00

(52) U.S. Cl. CPC H01J 37/20; B25J 7/00; H01J 2237/2007; H01J 2237/202; H01J 2237/2602

(57) ABSTRACT

A manipulating device for manipulating sample objects having dimensions between about 10 nm and 10,000 nm. The device is attached to a top plate of a microscope, wherein the top plate moves along a Z-axis. The device further has first and second arms attachable to said top plate, wherein when attached the first and second are positioned relative to one another to grasp a sample object. The first and second arms are adapted to move along an X-axis and a Y-axis. The device further has a controller adapted to control movement of the first and second arms.

### RELATED APPLICATION DATA

This application claims priority to International Application No. PCT/US14/38172, filed May 15, 2014, and U.S. Provisional Application No. 61/824,719, filed May 17, 2013, the contents of which are hereby incorporated by reference.

### BACKGROUND OF THE INVENTION

1. Field of the Invention

The present invention is directed to the field of sample preparation and analysis. In particular the invention is directed to the field of manipulating samples.

2. Description of the Related Technology

U.S. Pat. Nos. 7,053,383; 7,115,882; 7,126,132; and 7,126,133 discuss methods and apparatuses for sample preparation for TEM, the disclosures of which are hereby incorporated by reference in their entirety.

The use of focused ion-beam (FIB) microscopes has become common for the preparation of specimens for later analysis in a transmission electron microscope (TEM). The use of the FIB requires little preliminary mechanical preparation of the sample. In using FIB, techniques for cutting out lift-out specimens for examination are employed. These lift-out techniques include an ex-situ method that is performed outside the FIB microscope chamber, and in-situ methods performed inside the FIB microscope chamber.

An obstacle to handling, lifting and transferring objects (e.g. devices, structures, materials, etc.) with dimensions between 10-10,000 nm is the grabbing and handling of the objects. Omniprobe™ invented a single-probe lift-out method back in 1996, however it has several drawbacks. For instance, the final sample may not represent the bulk properties due to the use of materials employed during releasing (e.g. gallium) of the sample and during attaching (e.g. tungsten) of the sample. The probe also has limited motion accuracy, no force control and a different viewing angle than that of the electron beam. Moreover, there is no reliable tool to precisely transfer an object, such as nanotube, and place it at a desired location.

The process of in-situ lift-out can be broken down into three successive steps. The first is the excision of the sample using focused ion-beam milling and extraction of the sample from its trench.

The second is the holder-attach step, during which the sample is translated on the probe-tip point to the TEM sample holder. Then it is attached to the TEM sample holder, typically with ion beam-induced metal deposition. Later the sample is detached from the probe-tip point.

The third and final step is the thinning of the sample into an electron-transparent thin section using FIB milling. The relative amount of time involved in preparing the sample depends on the amount of time required to first mechanically isolate the lift-out sample from the initial bulk sample. This is controlled by the ion beam milling rate. The milling rate will typically constitute from 30% to 60% of the total time involved in the sample preparation.

In order to address the issues noted above as well as eliminate the holder-attach step, it would be desirable to directly join the probe-tip point with the sample attached to the material that will form the TEM sample holder.

### SUMMARY OF THE INVENTION

The present invention is directed to an apparatus for the manipulation of sample objects on the nanometer to micrometer scale.

An aspect of the present invention is a device for manipulating sample objects having dimensions between about 10 nm and 10,000 nm. The device comprises attachment means for attaching the device to a microscope, wherein the microscope has a top plate moveable along a Z-axis. The device further comprises first and second arms attachable to the top plate, wherein when attached the first and second arms are positioned relative to one another to grasp a sample object, and each of the first and second arms are adapted to move along an X-axis and a Y-axis; and a controller adapted to control movement of the first and second arms.

### BRIEF DESCRIPTION OF THE DRAWINGS

FIG. 1 shows a simplified side schematic view of the sample manipulator, in accordance with an embodiment of the invention.

FIG. 2 shows a simplified side schematic view of a microscale tip, in accordance with an embodiment of the invention.

FIG. 3 shows a simplified top down schematic view of a nanoscale tip, in accordance with an embodiment of the invention.

### DETAILED DESCRIPTION OF THE PREFERRED EMBODIMENT(S)

For illustrative purposes, the principles of the present disclosure are described by referencing various exemplary embodiments. Although certain embodiments are specifically described herein, one of ordinary skill in the art will readily recognize that the same principles are equally applicable to, and can be employed in other systems and methods.

Before explaining the disclosed embodiments of the present disclosure in detail, it is to be understood that the disclosure is not limited in its application to the details of any particular embodiment shown. Additionally, the terminology used herein is for the purpose of description and not of limitation. Furthermore, although certain methods are described with reference to steps that are presented herein in a certain order, in many instances, these steps may be performed in any order as may be appreciated by one skilled in the art; the novel methods are therefore not limited to the particular arrangement of steps disclosed herein.

It must be noted that as used herein and in the appended claims, the singular forms “a”, “an”, and “the” include plural references unless the context clearly dictates otherwise. Furthermore, the terms “a” (or “an”), “one or more” and “at least one” can be used interchangeably herein. The terms “comprising”, “including”, “having” and “constructed from” can also be used interchangeably.

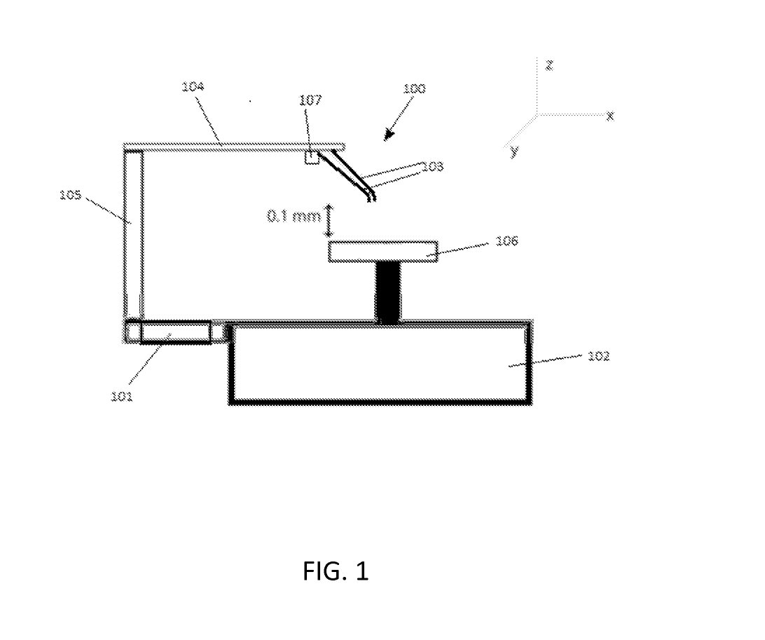

In order to address the problems discussed above an improved method and apparatus for manipulating objects is provided. Sample manipulator 100, shown in FIG. 1, offers a two-arm approach by which one can apply controllable amounts of force to hold an object, transfer an object and place it accurately at its destination. By eliminating steps, the conventional lift-out procedure is expedited. Further ion beam contamination is minimized, and manipulation capabilities inside the SEM chamber are enhanced. The sample manipulator 100 enables the operator to work with objects having a sized in the nanometer to micrometer range, using two different sets of manipulator transducers for each range.

As shown in FIG. 1, a controller 101 is installed on the stage 102 inside the electron microscope chamber and is operable with nanometer precision. The electron microscope chamber may be a vacuum chamber. Controller 101 programmed and/or installed with software providing instructions for controlling and operating sample manipulator 100. In operation, sample manipulator 100 uses the same viewing angle as the viewing angle of the electron beam. The use of the same viewing angle makes lift-out easier for the operator and additionally makes attachment of a sample object easier for the operator, e.g. a nanotube or cross-section sample. Preferably the sample objects have dimensions within a range of 10 nm to 10,000 nm, but some sample objects may have a size within a range of 1 nm to 100,000 nm. By “dimensions” it is meant the thickness, width or length of a sample object.

Controller 101 can also control the amount of force used to grab a sample object. Controlling the force used to grab a sample object can prevent damage that may be caused through use of excessive force. Controlling the force can further prevent premature and/or unwanted sample release.

Sample manipulator 100 may also have an extra degree of freedom by providing the ability to rotate the sample, in addition to having the ability to grasp and place the sample at the same angle. This enables the sample manipulator 100 to grasp a sample object from any given direction and/or location and to place the sample object from any given direction and/or location as well. For example, in electrical measurement experiments, a sample object such as a nanowire or cross-section lift-out, needs to be accurately placed between two contacts.

The sample manipulator 100 has first and second arms 103 that are used to grab and manipulate sample objects. The arms 103 are attached to a top plate 104. The arms 103 may be attached to an SEM microscope by way of welding or other means for attachment, such as clips, fasteners, screws, etc. The arms 103 are controlled by the controller 101 using two sets of transducers 107. One set of the transducers 107 is for coarse movement along the X-axis and Y-axis as referenced in FIG. 1. By coarse movement it is meant movement on a scale of 100 nm and above. Another set of transducers 107 is for fine movement along the X-axis and Y-axis. Transducers 107 are operatively connected to controller 101 by, for example, a wired or wireless connection (not shown).

By fine movement it is meant movement on a scale below 100 nm. Movement of the arms 103 along the Z-axis occurs via movement of the top plate 104 along the top plate support structure 105 though use of servo motors or mechanical controls since arms 103 are attached to top plate 104. Top plate 104 also permits rotation of arms 103 along the Y-axis. Operation and movement of arms 103 along any of the three axes may be controlled by the controller 101. The arms 103 are initially moved to a particular position in order to grasp sample object 106 that is located on the stage 102. In the embodiment shown in FIG. 1, two arms are used.

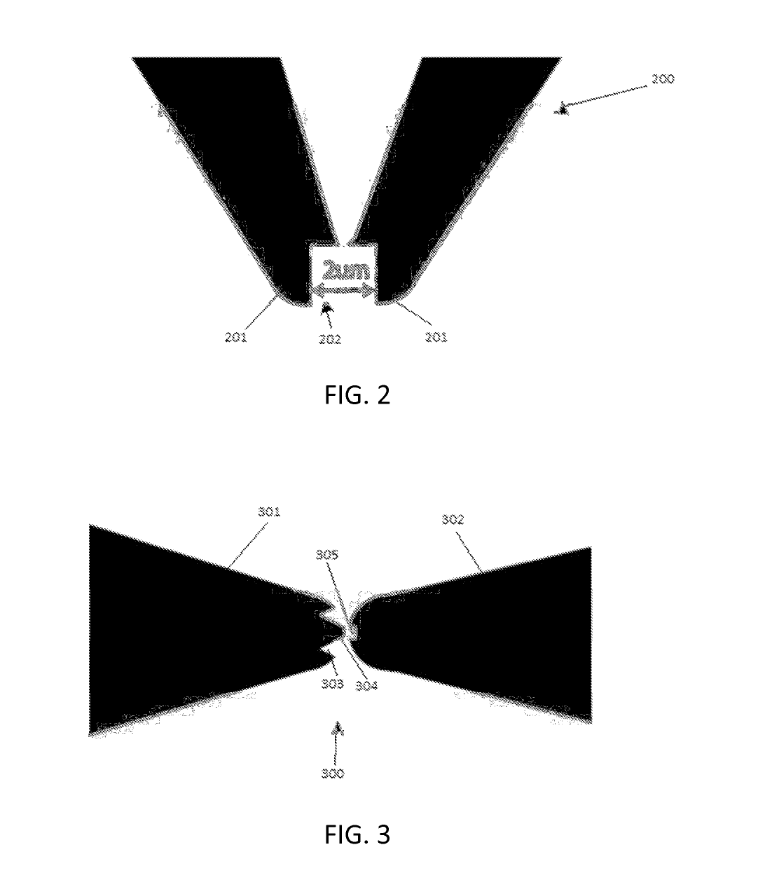

FIG. 2 shows a top schematic view of a microscale tip 200 and FIG. 3 shows a top schematic view of a nanoscale tip 300.

Referring to FIG. 2, the microscale tip 200 may be located at the distal ends of arms 103, shown in FIG. 1, when in use. The microscale tip 200 is formed by two microscale tip portions 201, wherein each microscale tip portion has an L-shaped cut-out 202. The microscale tip portions 201 form an acute angle with respect to each other when viewed top down. The L-shaped cut-outs 202 are used in the grasping of sample objects. The microscale tip 200 is used for microscale samples, such as a typical lift-out where the thickness of a sample object is within the range of 100 nm to 5 μm, preferably between about 2-3 μm. Microscale tip 200 is preferably constructed of a strong metal material that may deform rather than crack when in use, such as platinum, tungsten, etc.

Turning to FIG. 3, the nanoscale tip 300 may be located at the distal ends of arms 103, shown in FIG. 1, when in use. The nanoscale tip 300 is formed by two nanoscale tip portions 301 and 302. The nanoscale tip portions 301 and 302 form an obtuse angle with respect to each other, when viewed top down. First nanoscale tip portion 301 has two grooves 303 and a projecting portion 304. Second nanoscale tip portion 302 has a corresponding receiving groove 305 that may receive the projecting portion 304 when sample objects are being grasped. A controlled amount of force provided by the transducers 107 can be applied in order to hold nanoscale sample objects without damage or unwanted release.

Microscale tip 200 and nanoscale tip 300 may be attached to the arms 103 at separate times or may alternatively be integrally formed with the arms. It is also contemplated that in some embodiments the arms may comprise both microscape tip 200 and nanoscale tip 300.

Referring back to FIG. 1, in use the position of the tips can be correlated to the position of a sample object, because of use of the same viewing angle. This makes both lift-out and attachment of a sample object easier. Through use of the top plate 104 and support structure 105 the sample manipulator 100 automatically lowers the top plate 103 to distance of 100 μm from the surface of the sample object 106. Moreover, using the electron beam of the electron beam microscope to observe and maneuver the arms 103 maximizes operation accuracy.

It is to be understood, however, that even though numerous characteristics and advantages of the present invention have been set forth in the foregoing description, together with details of the method, composition and function of the invention, the disclosure is illustrative only, and changes may be made in detail, within the principles of the invention to the full extent indicated by the broad general meaning of the terms in which the appended claims are expressed.

What is claimed is:

1. A device for manipulating a sample objects having dimensions between about 10 nm and 10,000 nm, said device comprising:
first and second arms positionable relative to one another to grasp a sample object, wherein each of the first and second arms are adapted to move along an X-axis and a Y-axis;
attachment means for attaching the first and second arms to a movable plate of a microscope, wherein the plate is moveable along a Z-axis; and
a controller operatively connected to said first and second arms for controlling movement of the first and second arms along the X-axis and Y-axis.

2. The device of claim 1, wherein piezoelectric transducers operatively associated with the first and second arms are adapted to move the first and second arms along the X-axis and the Y-axis.

3. The device of claim 2, wherein there are two sets of piezoelectric transducers.

4. The device of claim 3, wherein one of the two sets of piezoelectric transducers is for coarse movement and one of the two sets of piezoelectric transducers is for fine movement.

5. The device of claim 4, said fine movement is movement of nanometer distances and coarse movement is movement of micrometer distances.

6. The device of claim 1, wherein the attachment means is configured to attach the device inside a vacuum chamber.

7. The device of claim 1, wherein said first and second arms comprise microscale tips and the microscale tips form an acute angle with respect to each other.

8. The device of claim 7, wherein the microscale tips further comprise L-shaped grooves.

9. The device of claim 1, wherein said first and second arms comprise nanoscale tips and the nanoscale tips form an obtuse angle with respect to each other.

10. The device of claim 9, wherein one of the nanoscale tips comprises a projecting portion.

11. The device of claim 10, wherein one of the nanoscale tips comprise receiving grooves.

12. The device of claim 1, wherein the controller is configured to control an amount of force applied by said arms.

13. The device of claim 1, wherein said controller correlates the position of said arms with respect to a location of the sample object.

14. The device of claim 13, wherein the controller uses data from an electron beam to control the location of said arms.

15. A microscope comprising:
a stage, and
the device of claim 1 operably attached to the stage.

16. The microscope as claimed in claim 15, wherein said microscope is selected from a scanning electron microscope and a transmission electron microscope.

17. The microscope as claimed in claim 15, wherein said microscope includes an electron beam and said controller controls movement of said arms by employing data from said electron beam.

18. The microscope as claimed in claim 15, wherein piezoelectric transducers move the first and second arms along the X-axis and the Y-axis.

19. The microscope as claimed in claim 18, wherein there are two sets of piezoelectric transducers.

20. The microscope as claimed in claim 19, wherein one of the two sets of piezoelectric transducers is for coarse movement and one of the two sets of piezoelectric transducers is for fine movement.
